(19) United States
(12) Patent Application Publication
(10) Pub. No.: US 2019/0237506 A1
(43) Pub. Date: Aug. 1, 2019

(54) LED LIGHT DEVICE

(71) Applicant: Cory Isaacson, Boomfield, CO (US)

(72) Inventor: Cory Isaacson, Boomfield, CO (US)

(21) Appl. No.: 16/264,284

(22) Filed: Jan. 31, 2019

Related U.S. Application Data
(60) Provisional application No. 62/624,641, filed on Jan. 31, 2018.

(51) Int. Cl. H01L 27/15; F21K 9/90; H05B 33/08; H05B 33/10

(52) U.S. Cl. CPC H01L 27/153; H05B 33/10; H05B 33/0824; F21K 9/90

(57) ABSTRACT

Various implementations of lights and methods of lighting using LEDs as the illumination source are provided. In various implementations, for example, a light including an LED strip, a method of embedding the LED strip in one or more layers of material to incorporate the LED strip holistically into an illuminaire, and a method of illuminating works of art to provide an even, faithful presentation to a viewer are provided.

### CROSS-REFERENCE TO RELATED APPLICATIONS

This application claims the benefit of U.S. provisional application No. 62/624,641 filed 31 Jan. 2018, which is hereby incorporated by reference as though fully set forth herein.

### BACKGROUND

### a. Field

The present disclosure relates to LED light devices and fixtures, such as illuminaires applied to room lighting, lighting of art work, and other applications.

### b. Background

There are many techniques for lighting art, and with the advent of improvements in LED technology many art lighting devices are now beginning to utilize LEDs as the light source. One purpose of art lighting is to illuminate a piece of art, such as a painting, photograph, drawing or other image, allowing the viewer an undistracted and pleasing view of the work. Further, the work should be presented with a faithful representation of the content, resulting in an aesthetic viewing experience.

Decorative lighting fixtures can also be used to illuminate interior or exterior spaces, such as a ceiling fixture providing general room lighting, a sconce for wall lighting or other similar applications. Decorative fixtures can hide the source of light from the user, and generally utilize lenses or physical barriers, including metal frames. These limitations can affect the aesthetics of the fixture, and limit the choices of the fixture designer.

Historically the illumination qualities of LEDs were harsh on the eyes and presented a sterile, white look, and thus did not adequately serve this purpose. In recent years LED technology has advanced, with improved color rendering index (CRI) capabilities. Thus LEDs have evolved to become a quality source of faithful illumination for art work. The same applies for room lighting; lighting of human skin or hair often looks sterile and washed out with older technology. In some specialized applications such as a cosmetologist station, this is a big detractor when using LEDs and non-LED light sources, including fluorescent illuminaires. Newer CRI spectrums illuminate people with a natural color in such applications.

In traditional art lighting, with LEDs or other light sources, the light is directed at a 30-degree angle to the art piece (FIG. 5). Directing the light at an angle is intended to minimize reflection to the viewer. In many applications, for example when the art piece is covered in glass or uses a reflective material for the work itself, the reflection with this approach is visible to the viewer from various angles and detracts from the art piece. Further, shining the light source at a 30-degree angle results in hot spots visible to the viewer, and illuminates the top portion of the art work more brightly than the mid- or lower-sections. The traditional method for art lighting is shown with the illuminaires at a 30-degree angle (503) to the art piece (502) hanging on a wall (501), the path of the light (504) and the reflection and hot spot reaching the viewer (505). This approach distracts the viewer from the art piece, and does not provide a faithful representation of the work, with some portions illuminated more brightly than others. In other cases, this approach results in hot spots at toward the horizontal center of the art piece (from left to right) from the viewer's position.

LED light sources are utilized in two general forms: a) as an LED strip (101), such as shown in FIG. 1, orb) utilizing individually mounted LEDs behind a lens or other translucent material to disperse the light. LEDs in an LED strip (101) are arranged in fixed-size segments of a plurality of individual LEDs (for example 6 individual LEDs) that are wired in serial (101). A plurality of fixed-size segments is then connected in a parallel circuit. This provides the proper voltage and current required to evenly light the LEDs in the strip. The method used to connect the plurality of fixed-size segments is a bus circuit (102) that runs the length of the LED strip.

Traditional LED design approaches provide the bus circuit along either side of the plurality of LEDs and LED segments (101). FIG. 1 shows an example LED strip (101); the bus is embedded in this configuration under the plastic insulator on the top and bottom of the strip. The position of the bus (102) to the sides of the LEDs and LED segments is shown by the dashed lines.

Many LED strips mount each individual LED cross-wise to the length of the LED strip (101), rather than length-wise. A cross-wise arrangement makes manufacturing and heat management easier to accomplish, but the resulting illumination may not be as even as compared with other configurations.

The bus circuit (102) and the cross-wise mounting of the individual LEDs (101) add width to the LED strip. These design approaches limit the use of LED strips in aesthetic light fixture or art light applications, and often necessitates hiding the LED strip or covering it with a lens or translucent material.

To control an LED circuit, including on/off, dimming and optionally color modulation capabilities, a driver is required to generate the proper voltage and current. LED drivers are typically housed in metal or plastic boxes and are hard to integrate into an aesthetic design for art lighting and room fixture applications, and detract from the illuminaire or subject art work.

### BRIEF SUMMARY

In various embodiments, a configuration for an LED strip, a method of embedding the LED strip in layers of transparent, translucent clear or colored material, to incorporate the LED strip holistically into an illuminaire, and a method of illuminating various subjects, such works of art to provide an even, faithful presentation to a viewer are provided.

In one embodiment, for example, an LED strip design that can be directly incorporated in aesthetic illuminaire design, including both light fixtures and art lights is provided. In one variation, the LED strip mounts the individual LEDs within a segment length-wise to the strip, and positions the bus connecting the plurality of segments on the bottom of the strip (FIG. 2). In variations, this can provide an extremely narrow LED strip, such that it can be embedded in aesthetic illuminaires in novel ways, such as one embodiment that embeds the LED strip in a transparent or translucent material, such as glass in the example shown (FIG. 8). In the example embodiment presented, placing the LEDs length-wise to the LED strip (301, 302) provides an aesthetic appearance to the LED strip and provides an even source of light without the need for a covering lens or translucent filter.

In other embodiments, a light fixture and a method of construction a light fixture are provided. For example, an LED strip is embedded in a glass fixture (FIG. 8) constructed from a plurality of layers of transparent, translucent or colored material, such as glass layers in one embodiment. In one variation, a slot is cut into one of the layers, the LED strip is inserted, and encased in a plasticized substance, such as clear epoxy resin in one embodiment (FIG. 9, 903). The LED strip in this configuration can also be very thin height-wise, only slightly thicker than the LEDs themselves. This can be as thin as 1-2 mm in some embodiments, and potentially less as new smaller LEDs are introduced to the market. In another embodiment, the LED strip can be inserted between any two or more layers of glass or other transparent or translucent material, with an epoxy or other filler, avoiding the need for a slot to be cut in the glass. The LED strip may be disposed, for example, with or without spacers between the layers. In other variations, the LED strip can be affixed in the slot without encasement in a plasticized substance, or the LED strip can be mounted in the surface of the transparent layers, or affixed to any other flat surface such as an interior or exterior illuminaire body or a wall or similar surface. In one implementation, the LED strip is embedded in a layer with one or a plurality of additional transparent or translucent layers, such that the configuration of layers shields the viewer's eyes from direct exposure to the LEDs. Optionally, a small form-factor LED driver can be embedded in one or more transparent, translucent or opaque layers in its own slot or a plurality of slots cut through the layers (FIG. 7, FIG. 8, 801, 802). In another embodiment, the transparent layers can be sandblasted, coated, acid-etched, or treated via one or more other processes to hide the LEDs from user view from various angles. This, for example, may avoid a need for multiple layers and for this purpose provides a simpler constructions. Connectors of various types, such as those presented (703, 901) can be embedded in the layers for the input from an external power source to feed the driver, which in turn powers the LED strip. In one implementation, fine wires are embedded (902) to connect the driver (904) and then the LED Strip (905), providing power to the components, using AWG 30 wires as an example configuration.

In another embodiment, a method for illuminating art works is provided, such that the subject art work is illuminated with an even wash of light across the width and height of the work, without hot spots and unnecessary reflections of the light source that may distract the viewer from the work (FIG. 6). In this embodiment, the method provided positions an LED light source offset from the work and facing generally downward (generally parallel to the work). The LED light source directs light from the LED(s) generally downward toward the floor from the offset position relative to the work in a direction generally parallel to the subject art work (603). In the particular embodiment shown in FIG. 6, the LED light source comprises an LED strip, such as described herein. In the embodiment using an LED light strip, a length of the LED strip can be configured to approximately fit the width of the subject art work, providing even illumination across the entire width of the work. In this example implementation, the method can take advantage of the natural illumination intensity spectrum commonly found in LEDs (405), with the strongest intensity vertically projected from the LED, and the weakest intensity from the edges of the LED as the angle of illumination approaches the horizontal. By aiming the LED light source vertically downward, in approximately a perpendicular (90-degree) angle in relation to the subject art work, the natural curve of the intensity spectrum can provide even illumination of the art work from top to bottom, with the weakest intensity striking the top of the art work closest to the source of illumination, and the stronger intensities striking the lower portion of the art work that are further from the light source (603, 604, 602). The light source may be disposed between 85 and 95 degrees in relation to the subject work, between 80 and 100 degrees, or such that the illumination of the work does not provide reflections to a viewer of the work.

### BRIEF DESCRIPTION OF THE DRAWINGS

FIG. 1 shows a typical LED strip.

FIG. 2 illustrates a detail of an example embodiment of an LED strip.

FIG. 3 shows an example embodiment of mounting individual LEDs in a segment within an LED strip.

FIG. 4 illustrates the circuit pattern and illumination pattern for the LEDs within the LED strip shown in FIG. 3.

FIG. 5 shows the typical projection angle and effect on a viewer for art lighting applications.

FIG. 6 illustrates an example projection angle for art lighting.

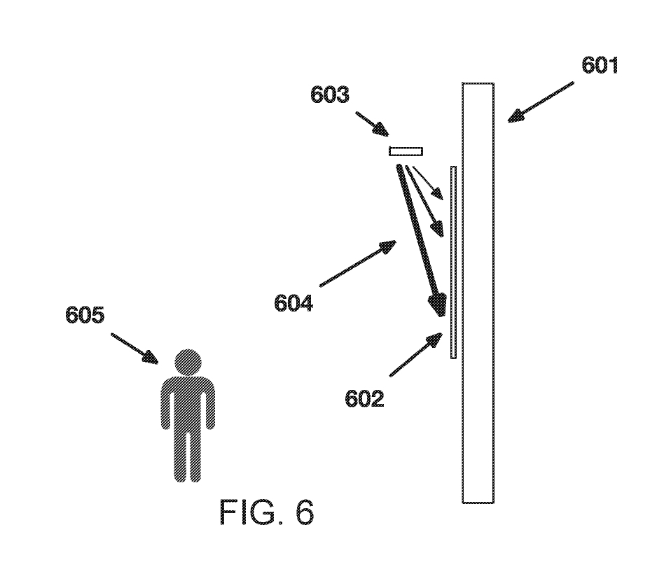

FIG. 7 shows an isometric view of an example layered fixture design.

FIG. 8 shows a side view of one embodiment of an LED strip and LED driver embedded in layers of material.

FIG. 9 shows a top view of an embodiment of a connector, LED Driver, LED strip and connecting wires embedded in a material and/or layers of a material. Embodiments, for example, may include disposing an LED strip within a material (e.g., a solid or hollow material), between two or more layers of material, embedding an LED strip in or mounting the LED strip on layers or other shapes of material, such as cubes, spherical or curved configurations.

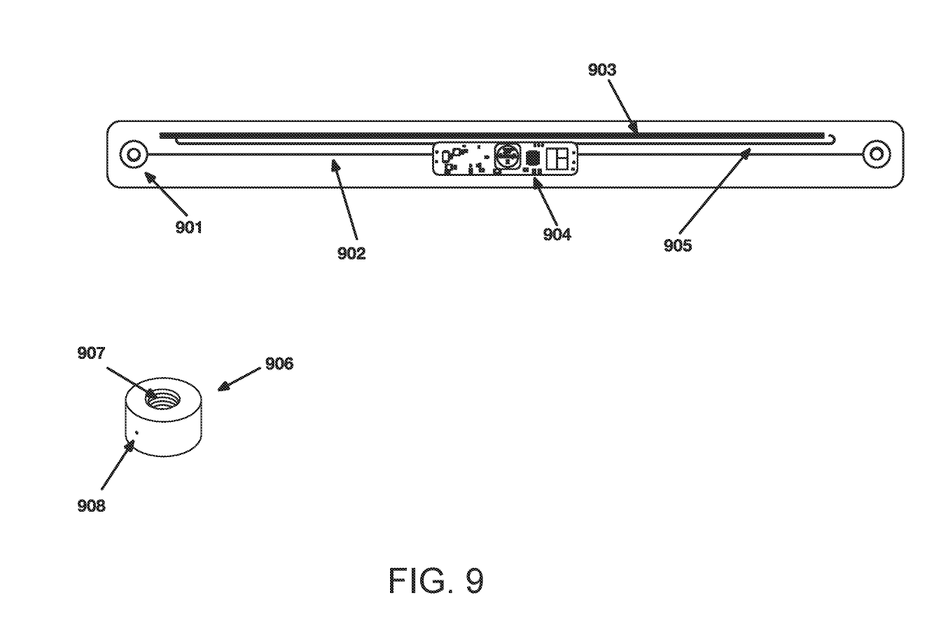

FIG. 10 shows a side view of another embodiment of an LED strip disposed between two layers of material.

### DETAILED DESCRIPTION

Various embodiments of LED strips are provided that allows for aesthetic applications in a variety of implementations and applications for decorative light fixtures and art lighting applications.

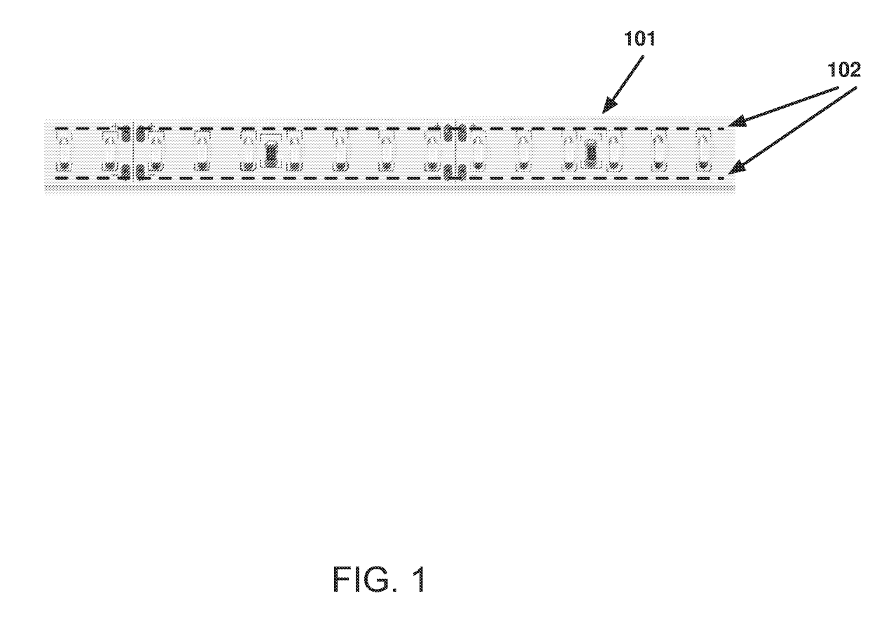

Traditional LED strips (101), such as shown in FIG. 1, resemble tape, with LEDs arranged cross-wise to the length of the strip (101). For LEDs to function they are generally connected with a serial circuit of a specified number of LEDs, forming an LED segment (101). In the example presented, the segments can be seen (101) containing 6 LEDs between exposed copper connection points. The copper connection points on either side of the LED strip segment provide a positive or negative polarity for the segment serial circuit, and each LED has one polarity as input and the opposite polarity for output. The LEDs are generally connected in series in this fashion, with the negative pole from one LED connecting to the positive pole of the next LED in the segment. A plurality of segments can then connected in a parallel circuit to create an LED strip of various lengths. Such a configuration provides the requisite amount of current and voltage to each segment, using a parallel circuit between the plurality of segments. A power source for the LEDs can be a special LED driver circuit that provides requisite direct current (DC) power to the LED circuit, in this case an LED strip. A parallel circuit for the plurality of segments can be supplied via a DC bus (102), indicated by the dotted lines shown (FIG. 1). In some implementations, the positioning of the bus circuit is to the outside of the LEDs, and adds width to the LED strip, resulting in typical widths of 0.25″ or more. This is commonly double the width of the LEDs themselves (or more), making it difficult to fit the LED strip into a given illuminaire design in an unobtrusive and aesthetic manner. Current technology for LED strips may embed the serial and parallel bus circuitry under insulated material, thus the bus in this example is embedded along with the circuit under the tape-like outer layer (102).

The design of current LED strips or other configurations of LEDs may require hiding or masking the LED strips with opaque or translucent barriers or lenses, to prevent visibility by the viewer of the illuminaire. This can be due to the appearance of the LED strip, being inadequate for decorative uses where the LED strip is directly exposed or visible to the viewer. This can limit design choices for a decorative illuminaire for room lighting fixtures or art lighting, where an important element is the appearance of the illuminaire device for the viewer, and how the illuminaire device fits with the subject room or art work. This can be true for room fixtures that must fit into the aesthetic appearance of the surrounding space, and can be applicable to the lighting of art work wherein the illuminaire must complement and not distract from the subject art piece.

These factors may restrict the placement of LED strips in an illuminaire for decorative or artistic applications, due to the extra width and unattractive appearance that often must be hidden or masked in the lighting fixture.

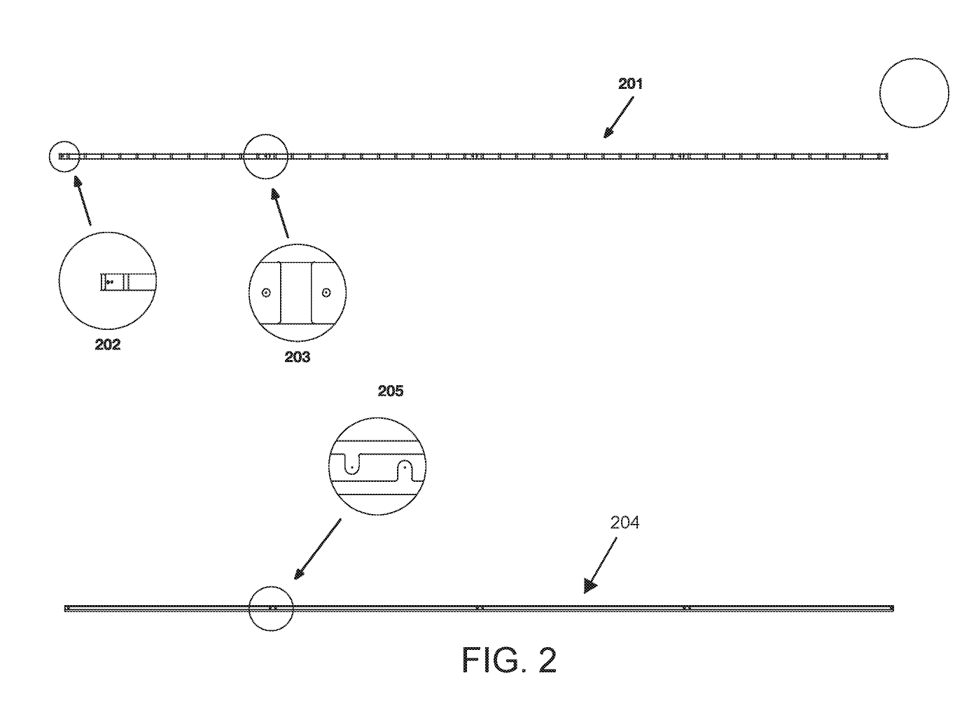

The embodiment shown in FIG. 2, for example, solves the aesthetic appearance issues from many aspects, by enabling a new form-factor for LED strips (FIG. 2). The form-factor provided allows for the LED strip to be applied directly within or as part of decorative lighting fixtures for room lighting, art lighting, or other applications where aesthetics and incorporation of the LEDs into the design in an attractive manner is important.

The configuration of the LED strip in the embodiment presented utilizes a thin, double-sided circuit board (203) or other conductive substrate to which the LEDs can be mounted or adhered (FIG. 2). In the example embodiment, the requisite circuit pattern is etched on a double-clad copper circuit board, with the requisite patterns etched on both the top (201) and bottom (204) surfaces of the circuit board (203). In this configuration, the top circuit provides serial connections between LEDs within each of the plurality of LED segments (201). In the example illustrated, the plurality of LEDs are positioned length-wise to the LED strip (302), but other mounting configurations of the LEDs can be used. In example configurations, each LED spans the gap in the circuit within one of the plurality of segments (201, 301, 404); one end of a single LED is the positive pole and the opposite end is the negative pole, thus the plurality of LEDs within a single segment are connected in a serial manner. At the end of each of the plurality of segments is a conductive through-hole (202, 203). This is used in the configuration presented the through-hole connects the positive or negative pole of the plurality of segments to the bus circuit (204, 205) on the bottom of the circuit board. In one embodiment, the through-holes for the segment circuit on the top of the circuit board are positioned exactly in the center width-wise of the LED strip circuit (203).

A bus circuit pattern (204) interconnecting the plurality of segments is presented, that runs length-wise along the bottom layer of the circuit board. In this configuration, one bus conductor provides the positive pole, and the other provides the negative pole of the DC circuit. In this embodiment, a circuit pattern is configured with special tabs (205) and through-holes (205) that exactly match and connect to the appropriate polarity position of the segment circuit on the top of the circuit board (203). This configuration allows the positive and negative terminating through-holes (203) for each segment to receive the correct polarity, in an alternating matter, with a given segment termination point receiving the positive pole and the opposite segment termination point receiving the negative pole of the circuit. In this way, the one or plurality of segments is powered appropriately, resulting in a parallel circuit of the plurality of segments.

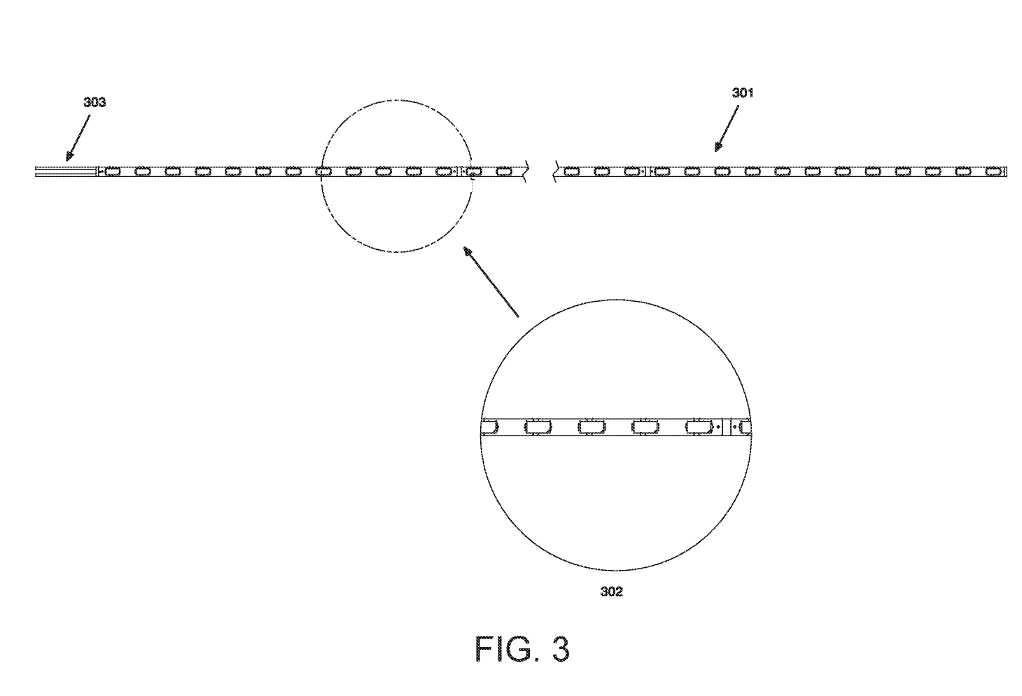

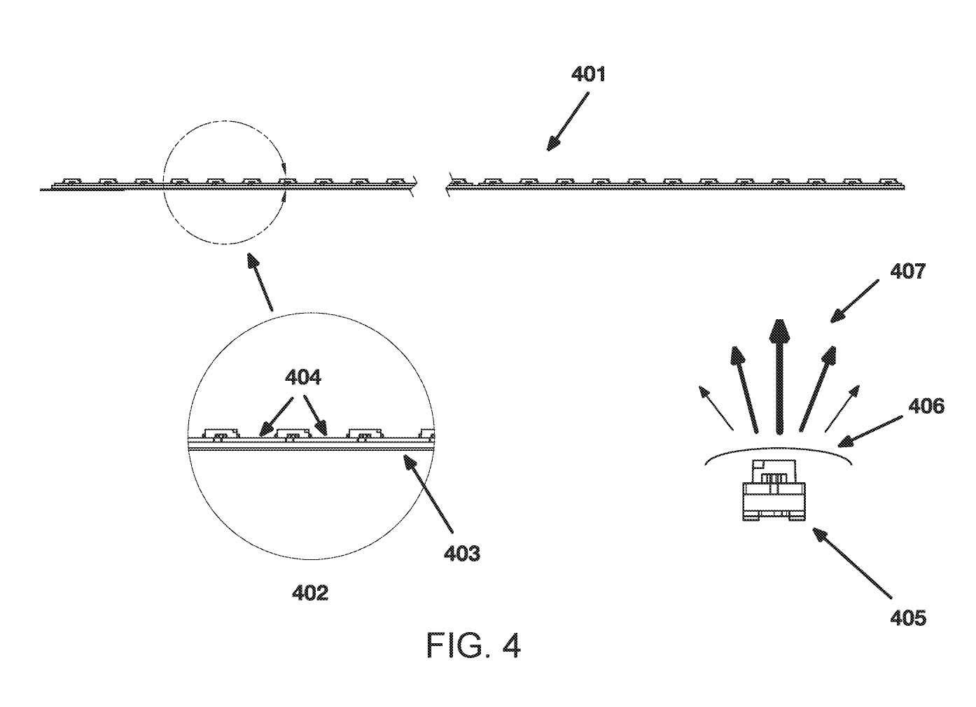

This implementation of the circuit offers three advantages: a) an LED strip configured in such a manner can be narrower than the traditional design, in the representative embodiment it is approximately width as the LEDs themselves (302), with other widths supported at the discretion of the designer of the illuminaire, b) the example configuration and arrangement of the circuit preserves a simple and aesthetic appearance that can remain visible to the viewer of the illuminaire, including direct visibility of the copper or other conductive material on the circuit board (FIG. 3, FIG. 4) if desired by the designer of the illuminaire, and c) the LED strip can optionally be formed in a straight linear pattern as shown in the embodiment presented (FIG. 2), or can alternatively be formed in a curved pattern to accommodate an illuminaire fixture with curved lines. Another advantage is that the height dimension can be extremely thin, allowing the LED strip to be mounted between any two layers of transparent or translucent material (such as glass), using a clear epoxy or other filler. These configurations and variations are numerous, offering a broad array of flexible design choices for the designer of a lighting fixture or other lighting application.

The LEDs, if rectangular in configuration as the present embodiment illustrates, can optionally be mounted length-wise on the top pattern of the circuit board (301, 302, 401). In this implementation, each LED is mounted within a given segment, spanning the gap of the circuit pattern (302, 404), without overlapping or spanning the segment terminating through-holes (302). Individual LEDs may be affixed to the top circuit such that a conductive bond is created to each portion of the plurality of circuit connection points (203, 302, 404). In one embodiment, the LEDs are affixed with solder using flow-based solder paste or other solder application technique; in another embodiment, they are affixed with a conductive epoxy glue; other embodiments, such as conductive ink may be used as long as a conductive bond is created between the LED and the LED circuit. The embodiment presented of an arrangement of LEDs in close, even spacing, may be used to provide an even source of light for decorative applications. Such an even source of illumination can be important for art work illumination, and allows the strip to be applied or integrated into a fixture, reducing the need for a translucent lens for masking or dispersing the light.

A plurality of LED strips may be interconnected using extensions to the bus circuit of a given LED strip (303), enabling any desired length to be accommodated based on the requirements of a given fixture, art light or other illuminaire.

These characteristics combine in the present embodiment to provide an even source of illumination that can accommodate a wide variety of aesthetic designs for room lighting, art work lighting, or other illumination requirements.

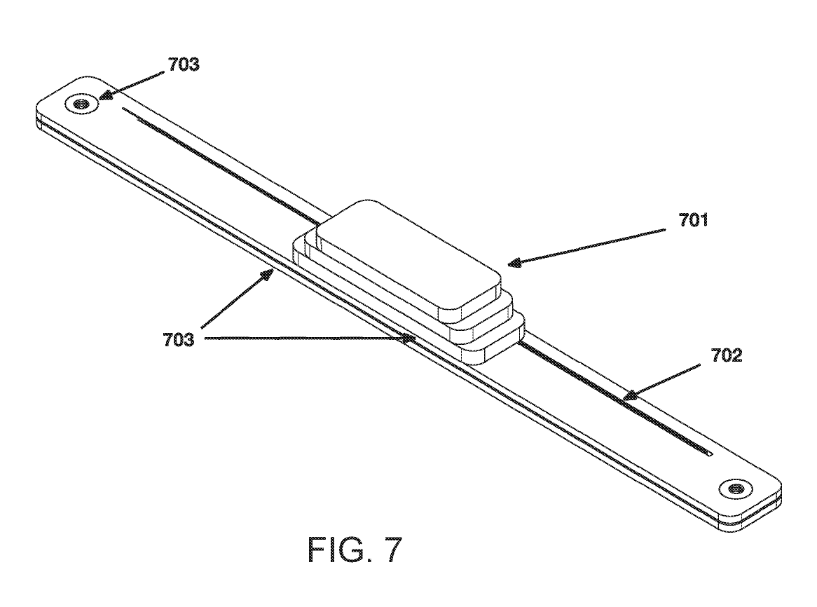

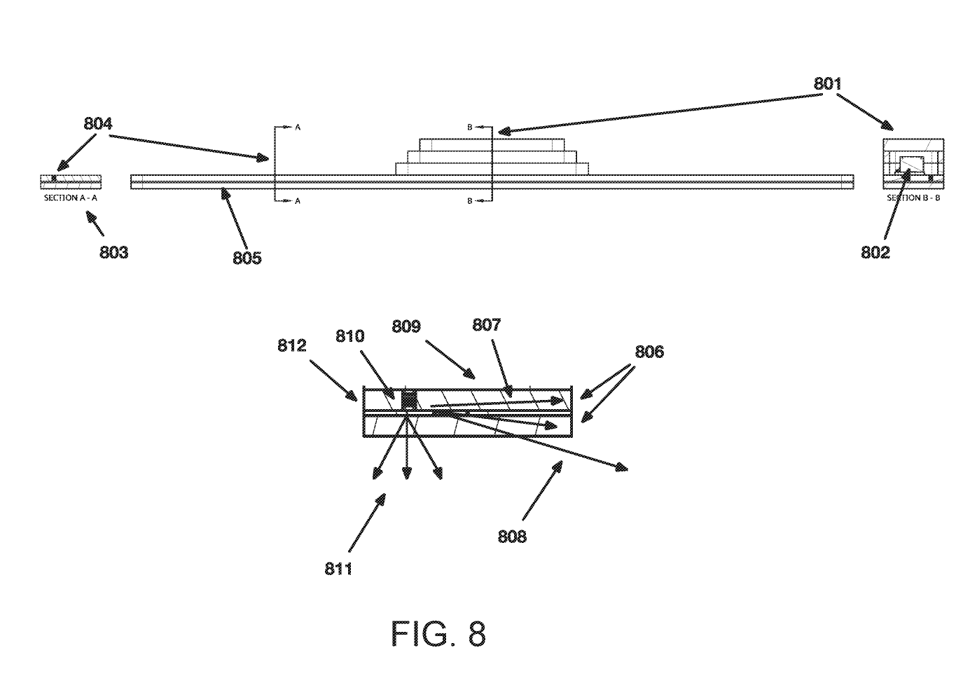

Various embodiments provide a device and configuration for seamlessly integrating the LED strip in various ways into a light fixture constructed of layers of material, that can be transparent, translucent, colored or opaque (FIG. 7, FIG. 8). In the present embodiment layers of glass are used as the material. Other material configurations can be used, including blocks, cubes, spherical or curved implementations. In the example implementation, the LED strip is embedded in the one or plurality of layers, suspended in a plasticized material such as epoxy. Other variations can support embedding or fixing the LED strip in the layer without a plasticized substance, or affixing the LED strip to the outside of a layer, fixture, material or other object such as a wall or a piece of furniture.

In some embodiments, a channel is cut in a layer of material in which to embed the LED strip (702, 903). A top layer is used some examples; any layer can be used according to design goals for the fixture. In one configuration, an LED strip is set into the channel using a transparent plasticized substance, such as clear epoxy resin that hardens and bonds with the layer. A plasticized substance may be used in this manner to fill the layer channel, encasing the LED strip (702, 903) and blending with the layer material. Some example embodiments use glass as a layer material, but other materials may be used for the layers.

In other variations, the LED strip may be mounted within a channel by affixing the LED strip to the layer. Additional variations may affix or mount the LED strip onto the surface of a layer or other shape of material. For example, the LED strip may be affixed to the underside of a table, a furniture piece, to a wall, a ceiling, or other light fixture configuration as the application requires.

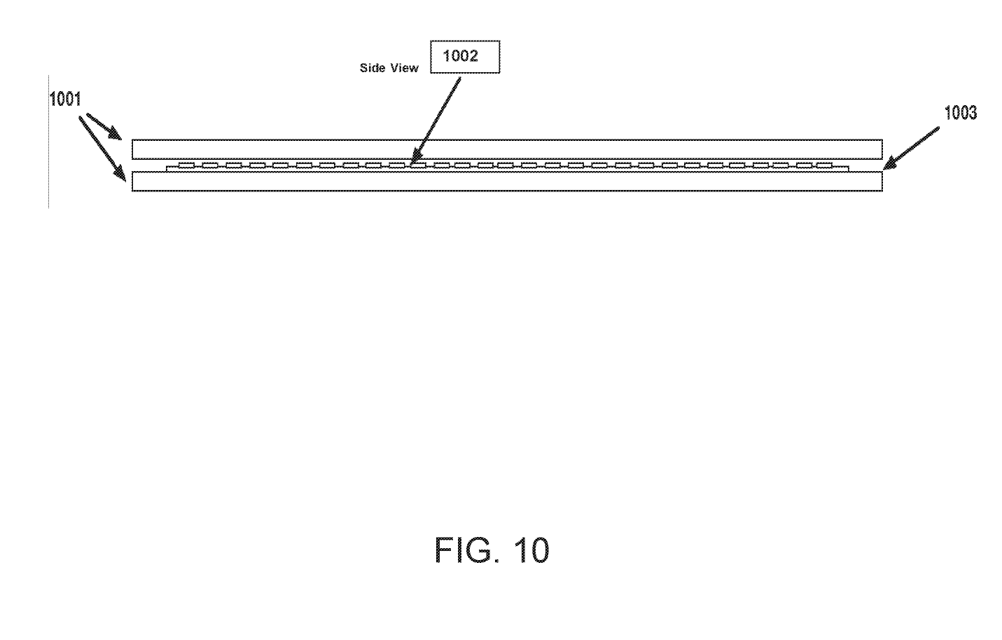

In another embodiment the LED strip can be inserted between any two or more layers of translucent or transparent material with or without spacers such as shown in FIG. 10, using clear epoxy, polyurethane or other material to adhere the layers and embed the LED strip in the small space between the layers.

In various embodiments, an LED strip can be mounted such that the illumination is directed in a downward angle (702, 804), roughly perpendicular to or at a steep angle to a subject art work. In other variations, any direction can be selected, including upward or to any side of the fixture, from an embedded or surface-mounted position within or on the fixture. Downward illumination may be used for an art work lighting application.

The LED can also be embedded in a transparent or translucent layer parallel to the edge of the glass or other material. In this embodiment the light is directed through the width of the layer, illuminating the edges or surfaces above or below the glass or other material as desired. For example, individual glass layers for a room lighting fixture can be suspended such that the panes are vertical to the room or ceiling, with the LED strips directed up or down as desired.

As described earlier, an LED lighting configuration may use an LED driver, a special circuit and components that provide the requisite power, dimming and color control capabilities for the LED strip within a lighting fixture or other application. In the example illustrated, the LED driver circuit incorporates a Bluetooth® Low Energy component, enabling remote control of the LED lights for dimming and optionally color via any Bluetooth®-enabled device such as a smart phone, tablet or computer. Bluetooth® remote control can be used for multi-color LED controls that respond to red-green-blue (RGB) settings for each individual LED, and can be driven by a computer program for dynamic effects.

In the embodiment presented, an LED driver circuit board can be incorporated and embedded into the layered fixture design (701, 801, 904) as shown. Alternatively the driver can be mounted exterior to the fixture, with the controlled current provided via wiring or other conductive facility. In an example embodiment, the LED driver circuit board is in a small form-factor, approximately 0.5″ wide by 2.75″ long and less than ⅛″ in height. In other implementations, the form factor can be even smaller, as narrow as 0.25″ wide by 3″ long and approximately 1/16″ in height. As electronic components improve, these dimensions could be even smaller. This configuration allows the driver to be embedded in a single layer of ⅛″ material, or across multiple layers for different configurations as in the example illustration (802). The driver may be mounted in its own slot cut into the glass layer using epoxy, polyurethane or other clear or colored translucent material. Alternatively, the driver can be mounted between any 2 layers in the space between the layers with epoxy resin or other clear material to affix it. This approach gives the visual illusion of the driver mounted in the glass or transparent material itself.

In the embodiment presented, special connectors (703, 901, 906) are provided to bring power to the fixture, typically a constant voltage source; 24 v DC power is used for the present embodiment, but many other power source variations can be used. The connectors presented in this particular embodiment are round donut-shaped components (906), thin enough to fit within a single layer of the fixture in the present implementation. Other connector configurations can be used, as long as they provide conductive material and integrate into the design of the fixture or other application for the LED strip. In this implementation, the connectors have a threaded center (907) enabling a power feed to the fixture from an energized threaded stud or bolt, as one option of providing power to the fixture. The implementation for a connector provides one or more small holes in the side (908) for easy attachment of a wire conductor (902). Connectors could be other shapes, or could be wires that extend beyond the fixture and are attached to any power source.

In various embodiments, connections to components can utilize very thin gauge 30 AWG wire (902); this is an aesthetic design choice, and other variations may be used. A thin wire is embedded between transparent layers, optionally inside a thin layer of plasticized material (805), such as clear epoxy resin in the embodiment illustrated. Such a wire can be affixed by other means as well, such as gluing the wire to a surface if desired. For the present embodiment, a thin wire was selected as it is nearly invisible to the viewer, and can be seamlessly embedded between layers. With other material configurations, and in other applications, many variations for connectivity between components may be used.

As shown in example embodiments, 24 v DC power is provided to the fixture by an energized stud or bolt that screws into the threaded connector (901). The implementation then connects the 24 v DC power to an LED embedded driver circuit (904) via a thin gauge wire (902). Alternatively, the driver can be powered with 12V DC power. An LED driver provides the requisite voltage and current to power the LED strip (903) via a thin gauge wire (905) for this implementation; many other configurations may be used. An output wire from the driver is connected via solder or other conductive means to the positive or negative LED strip bus (205). In the present embodiment, the wires are shown connected to the ends of the bus, but they can be connected at any point using. In this embodiment, the power from the driver to the LED strip bus can be connected at any pair of the special tabs (205) between any of the plurality of segments, with a connection to the positive pole and another connection to the negative pole bus circuit.

In other variations, the LED driver can be mounted exterior to the fixture, such as a wall mounting. In this case, a requisite voltage and current needed by the LED strip are connected directly via a connector (703, 901) to an accessible tab of the LED strip bus (205).

One particular embodiment provides for a special application, illuminating a work of art. This application integrates all other features of the embodiments and implementations described.

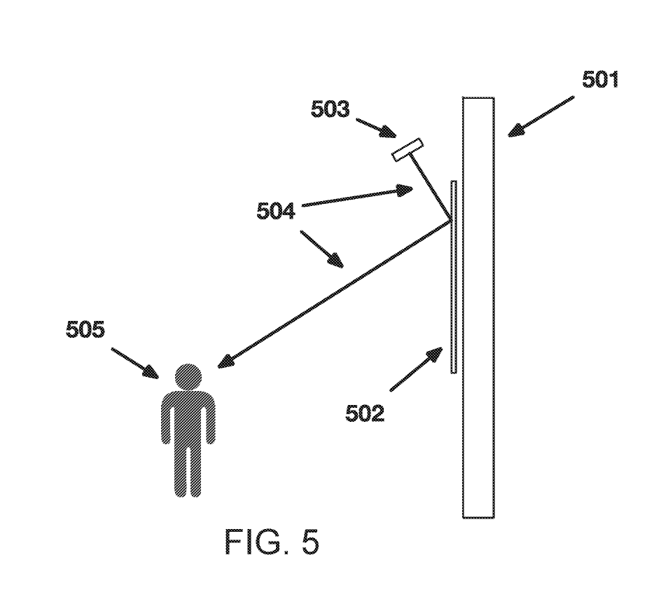

An art piece (502) is typically hung or mounted on a wall (501), and is illuminated for viewing by a viewer (505) as shown in FIG. 5. The typical arrangement for art work illumination places an art light at a 30-degree angle to the work (503). This creates the focus of light near the top of the art piece (504), and then may reflect toward the viewer from various angles (504, 505). This may cause a reflection of the light source itself toward the viewer, which can distract from the art work. This approach may also result in hot spots, where the light is most intense at or near the top or top-center of an art work, leaving a lower portion of an art work with less illumination. This may not faithfully represent the art work and an intention of the artist, and thus such rendition for the viewer may be non-optimum.

LEDs emit illumination in a radial pattern (406, 407) that spans many degrees. In one embodiment, for example, an LED radial pattern range spans 120-degrees (406), wherein the strongest intensity of light is directly perpendicular to the base of the LED and the intensity weakens as the pattern (407) approaches the parallel, horizontal plane with a base of an LED (405). This radial pattern and varying intensity may exacerbate the hot spots and reflection issues described above. In some configurations, translucent filters or other deflectors are used to counteract these deficiencies; these may weaken or lessen the illumination source, possibly reducing the amount of light applied to the subject art piece.

In one embodiment, a method for taking advantage of the radial spectrum emitted by many types of LEDs (406, 407) is provided. An LED strip, for example embedded in a fixture constructed of layers (such as shown in FIG. 7) can be mounted horizontally above (603) and at an appropriate distance in front of the subject art work (602). The configuration illustrated directs the LEDs at a perpendicular or steep angle to the art piece (603), such that a weakest intensity portion of the radial spectrum (604) illuminates the top portion of a subject art work (602) and a strongest intensity portion of the spectrum (604) illuminates the bottom portion of a subject art work (602), with intensity gradients (604) in between illuminating a mid-portion of the subject art work (602). In this implementation, the LED light source (603) is closer to an upper portion of a subject art work (602), and is further from a bottom portion of a subject art work (602) the overall illumination of the subject art work (602) can provide even illumination from top to bottom. This implementation accomplishes such an even illumination because areas of a subject art piece that are closer to the LED, and thus the source of illumination, receive more intense illumination than an area of a subject art piece that are further from the illumination source (604). In this embodiment, the weaker illumination is cast on an upper portion of a subject art work that is closer to the fixture, and the stronger illumination is cast toward lower portions of a subject art work in a gradient illumination intensity spectrum (604). Thus the method provides for even illumination across a subject art work from top to bottom.

Another aspect of this embodiment directs the light in a downward direction in relation to the art work, for example toward the floor at an approximately perpendicular angle to the surface of a subject art work (603). This implementation method can avoid or reduce hot spots or reflection of the light source toward the viewer (605). LEDs can be used in the LED strip (such as shown in FIGS. 3 and 4) with a broad CRI range to illuminate colors of a subject art work (602) brightly and faithfully to an artist's intent. Other types of LEDs with varying characteristics may be used for other desired lighting effects. In other variations, the method may be applied to lighting decorative walls or other similarly planar surfaces, vertical surfaces or other types of in-relieve art works. Artists may incorporate such lighting into a subject art work itself.

FIG. 7 shows an implementation in which a light fixture housing an LED strip (such as shown in FIGS. 3 and 4) may be constructed from layers of transparent, translucent, or colored material (703) as described. Other types of material and shapes may be used for additional variations as described earlier. As an example, layers (703) may be cut to a desired size and shape from glass material using a water jet cutter. This particular embodiment is illustrated for an art light application, however in other variations similar techniques and methods can be applied to virtually any type or shape of room lighting, or physical lighting application.

LEDs can be very bright and uncomfortable for the viewer if viewed directly. In the present embodiment, vertical cut edges of one or a plurality of layers (703) in are translucent (806) as a result of a cutting process. Similarly a grinding process may be used for similar effect. This configuration provides a filter and a trap for light in the direction of the edges, as illustrated in this example the horizontal direction. This method is one variation to shield the viewer's eyes from direct viewing of the plurality of LEDs in the LED strip (such as shown in FIG. 3) from the point of view of the viewer. Alternatively, the glass or other material can be treated in specific areas with sandblasting, acid-etching, or through application of a translucent material to shield the viewer's eyes from the distraction of the LEDs from the viewer's point of view, without shielding the light toward the subject work of art. For the art lighting application, an LED strip can be embedded in the top transparent layer of material (804, 810) in proximity to the horizontal edge that is closest to the subject art work (812), with an LED strip facing downward, optionally through one or a plurality of additional layers. In the example implementation, horizontal surfaces of layers are relatively transparent (809) allowing illumination to pass through with less obstruction (811) as compared with the translucent edges of the material, while the direct view of the LEDs is shielded by translucent vertical edges toward the viewer (806) on the opposing side of the subject art work. This method can to trap or diffuse direct light beams of the LEDs in an LED strip (810) via a translucent cut surface (807), controlling any direct beam toward the eyes of the viewer (808). In this implementation a steep angle of the illumination source (810) in relation to the vertical cut edge of the lower transparent material (806) is provided. The implementation additionally allows a relatively unobstructed travel of light beams toward a subject art work (811). By adjusting and varying the configuration, size, shape, width, thickness of number of layers (703), the number and thickness of translucent cut edges of layers (806) can be varied to allow the desired illumination of a subject art work. This configuration and variations thereof can protect a viewer's eyes from direct viewing of the bright LEDs by controlling the penetration angle of an illumination (808) escaping with less obstruction through a transparent horizontal surface of one or a plurality of layers (809). This technique can be applied to room or other lighting applications as well with many variations.

A driver, embedded in a fixture (904) or mounted at an exterior location can optionally be used to adjust brightness or color of an LED strip (such as shown in FIG. 3). Use of a driver in this fashion allows control of an amount of light illuminating from a fixture on to a subject art work (602) or other subject such as a room or object.

Although implementations have been described above with a certain degree of particularity, those skilled in the art could make numerous alterations to the disclosed embodiments without departing from the spirit or scope of this invention. All directional references (e.g., upper, lower, upward, downward, left, right, leftward, rightward, top, bottom, above, below, vertical, horizontal, clockwise, and counterclockwise) are only used for identification purposes to aid the reader's understanding of the present invention, and do not create limitations, particularly as to the position, orientation, or use of the invention. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other. It is intended that all matter contained in the above description or shown in the accompanying drawings shall be interpreted as illustrative only and not limiting. Changes in detail or structure may be made without departing from the spirit of the invention as defined in the appended claims.

What is claimed is:

1. A method of producing an LED device comprising:
providing an LED strip; and
disposing the LED strip in at least one transparent or translucent material to incorporate the LED strip into an illuminaire.

2. The method of claim 1 wherein the LED strip is disposed between at least two layers of the transparent or translucent materials.

3. The method of claim 2 wherein the LED strip is embedded between the at least two layers.

4. The method of claim 1 wherein the LED strip is embedded within the material.

5. The method of claim 3 wherein the LED strip is embedded within an adhesive within the material or between the at least two layers.

6. The method of claim 1 wherein the material comprises a clear or colored material.

7. An LED strip device comprising:
a plurality of LEDs disposed in a segment length-wise to a strip, and
a bus connecting the plurality of segments, the bus disposed on a first side of the strip.

8. The LED strip of claim 7 wherein the first side comprises a bottom side of the strip.

9. The LED strip of claim 7 wherein the LED strip is disposed (i) within a material or (ii) within or between at least two layers of the material.

10. The LED strip of claim 9 wherein the LED strip is embedded (i) within the material or (ii) within or between the at least two layers of the material.

11. The LED strip of claim 7 wherein the plurality of LEDs are disposed into a plurality of segments in which the LEDs of each segment are disposed length-wise relative to the strip.

12. The LED strip of claim 11 wherein the bus connecting the plurality of segments is disposed on a bottom side of the strip.

13. The LED strip of claim 7 wherein the plurality of LEDs are disposed lengthwise along the LED strip and provide an even source of light without a lens or translucent filter.

14. A light comprising:
an LED strip comprising a plurality of LEDs;
a transparent or translucent material or plurality of layers of the material, wherein the LED strip is disposed (i) within the material or within or (ii) within or between the plurality of layers of the material.

15. The light of claim 14 wherein the LED strip is disposed within a slot formed in the material or at least one layer of the plurality of layers of the material.

16. The light of claim 14 wherein the LED strip is affixed to the material or at least one layer of the plurality of layers of the material via a plasticized material.

17. The light of claim 16 wherein the plasticized material comprises a transparent or translucent epoxy resin.

18. The light of claim 14 wherein the LED strip is affixed to the material or at least one layer of the plurality of layers of the material via an adhesive.

19. The light of claim 16 wherein the LED strip is encased within the plasticized material or adhesive.

20. The light of claim 14 wherein the LED strip is mounted in a surface of the material or at least one of the plurality of layers of the material.

21. The light of claim 14 wherein the LED strip is mounted to a surface of the material or at least one of the plurality of layers of the material.

22. The light of claim 14 wherein the LED strip is affixed to a surface of the material or at least one of the plurality of layers of the material.

23. The light of claim 14 wherein the LED strip is affixed to a slot or opening of the material or at least one of the plurality of layers of the material

24. The light of claim 14 wherein the LED strip is disposed within at least one layer of the plurality of layers.

25. The light of claim 14 wherein at least one of the plurality of layers shields a viewer's eyes from direct exposure to the plurality of LEDs.

26. The light of claim 14 wherein the light strip comprises an LED driver.

27. The light of claim 14 wherein an LED driver is disposed in or adjacent to the material or at least one of the plurality of layers of the material.

28. The light of claim 14 wherein the LED driver is disposed in one or more transparent, translucent, or opaque layers.

29. The light of claim 28 wherein the LED driver is embedded within one or more transparent, translucent, or opaque layers.

30. The light of claim 28 wherein the LED driver is disposed within a slot or a plurality of slots formed in the material or at least one of the plurality of layers.

31. The light of claim 28 wherein at the LED driver is coupled to the LED strip to power the LED strip.

32. A method of illumination comprising:
providing LED light oriented to direct light in a generally downward, wherein the LED light is offset from a target of illumination,
lighting the target via the LED light such that the target work is illuminated

33. The method of claim 32 wherein the target is illuminated with an even wash of light across the width and height of the target without hotspots or extraneous reflections of the light source.

34. The method of claim 32 wherein the LED light is oriented to direct light downward toward a floor at a generally 90 degree downward angle to the target.

35. The method of claim 32 wherein the LED light is oriented to direct light downward in a generally parallel plane to the target toward a floor.

36. The method of claim 32 wherein the LED light is oriented to direct light toward the floor within a plus or minus angle of twenty degrees from vertical, within a plus or minus angle of fifteen degrees from vertical, within a plus or minus angle of ten degrees from vertical, within a plus or minus angle of five degrees from vertical, within a plus or minus angle of four degrees from vertical, within a plus or minus angle of three degrees from vertical, within a plus or minus angle of two degrees from vertical, within a plus or minus angle of one degree from vertical, or within a plus or minus angle of one-half a degree from vertical.

37. The method of claim 32 wherein the LED light is oriented to direct light toward the floor within an angle of twenty degrees from vertical, within an angle of fifteen degrees from vertical, within an angle of ten degrees from vertical, within an angle of five degrees from vertical, within an angle of four degrees from vertical, within an angle of three degrees from vertical, within an angle of two degrees from vertical, within an angle of one degree from vertical, or within an angle of one-half a degree from vertical.

38. The method of claim 32 wherein the illumination comprises relatively stronger illumination projected at a generally vertical direction and relatively weaker illumination projected from an edge of the LED light toward an angle varying from the generally vertical direction toward the target.

39. The method of claim 32 wherein by aiming the LED light source vertically downward, in approximately a perpendicular angle in relation to the subject art work, the natural curve of the intensity spectrum can provide even illumination of the art work from top to bottom, with the weakest intensity striking the top of the art work closest to the source of illumination, and the stronger intensities striking the lower portion of the art work that are further from the light source.

40. A light comprising:
an LED strip comprising a plurality of LEDs;
a dual clad circuit board comprising a top and/or bottom circuit.

41. The light of claim 40 wherein the LED strip comprises at least one shape or pattern selected from the group comprising: a straight shape, a curved shape,
